(19) United States
(12) Patent Application Publication
(10) Pub. No.: US 2015/0243813 A1
(43) Pub. Date: Aug. 27, 2015

(54) SOLAR CELL, METHOD FOR MANUFACTURING THE SAME, AND SOLAR CELL MODULE

(71) Applicant: LG ELECTRONICS INC., Seoul (KR)

(72) Inventor: Hyeyoung YANG, Seoul (KR)

(73) Assignee: LG ELECTRONICS INC., Seoul (KR)

(21) Appl. No.: 14/593,315

(22) Filed: Jan. 9, 2015

(30) Foreign Application Priority Data
Feb. 24, 2014 (KR) 10-2014-0021553

(51) Int. Cl. H01L 31/0224; H01L 31/18; H01L 31/048

(52) U.S. Cl. CPC H01L 31/022441; H01L 31/048; H01L 31/18

(57) ABSTRACT

A solar cell, a method for manufacturing the same, and a solar cell module are discussed. The solar cell includes a semiconductor substrate including a plurality of first electrodes and a plurality of second electrodes, which are separated from each other on a back surface of the semiconductor substrate, and an insulating member including a first auxiliary electrode connected to the plurality of first electrodes and a second auxiliary electrode connected to the plurality of second electrodes on a front surface of the insulating member. The insulating member is positioned on portions of the first and second auxiliary electrodes disposed on the back surface of the semiconductor substrate, and also extends over non-formation portions of the first and second auxiliary electrodes.

### CROSS-REFERENCE TO RELATED APPLICATION

This application claims priority to and the benefit of Korean Patent Application No. 10-2014-0021553 filed in the Korean Intellectual Property Office on Feb. 24, 2014, the entire contents of which are incorporated herein by reference.

### BACKGROUND OF THE INVENTION

1. Field of the Invention

Embodiments of the invention relate to a solar cell, a method for manufacturing the same, and a solar cell module.

2. Description of the Related Art

A solar cell generally includes a substrate and an emitter region, which are formed of semiconductors of different conductive types, for example, a p-type and an n-type, and electrodes respectively connected to the substrate and the emitter region. A p-n junction is formed at an interface between the substrate and the emitter region.

As described above, the solar cell using the semiconductor substrate may be classified into a conventional type solar cell and a back contact solar cell depending on its structure.

In the conventional type solar cell, an emitter region is positioned at a front surface of a substrate, electrodes connected to the emitter region are positioned on the front surface of the substrate, and electrodes connected to the substrate are positioned on a back surface of the substrate. In the back contact solar cell, an emitter region is positioned at a back surface of a substrate, and all of electrodes are positioned on the back surface of the substrate.

### SUMMARY OF THE INVENTION

In one aspect, there is a solar cell including a semiconductor substrate including a plurality of first electrodes and a plurality of second electrodes, which are separated from each other on a back surface of the semiconductor substrate, and an insulating member including a first auxiliary electrode connected to the plurality of first electrodes and a second auxiliary electrode connected to the plurality of second electrodes on a front surface of the insulating member, wherein the insulating member is positioned on portions of the first and second auxiliary electrodes disposed on the back surface of the semiconductor substrate, and also extends over non-formation portions of the first and second auxiliary electrodes.

The insulating member may include a first insulating member overlapping the first auxiliary electrode and a second insulating member overlapping the second auxiliary electrode. The first insulating member may be spatially separated from the second insulating member. The back surface of the semiconductor substrate may be exposed to a separation space between the first and second insulating members.

The first auxiliary electrode may include a plurality of first connectors, which are connected to the plurality of first electrodes and extend in a first direction, and a first pad which are connected to ends of the plurality of first connectors and extend in a second direction. The second auxiliary electrode may include a plurality of second connectors, which are connected to the plurality of second electrodes and extend in the first direction, and a second pad which are connected to ends of the plurality of second connectors and extend in the second direction.

The first and second insulating members may be formed in a portion overlapping the first and second connectors and the first and second pads. Further, the first insulating member or the second insulating member may not be formed in a portion not overlapping the first and second connectors and the first and second pads.

In another aspect, there is a method for manufacturing a solar cell including a connection operation for connecting an insulating member including a first auxiliary electrode and a second auxiliary electrode, which are separated from each other, to a back surface of a semiconductor substrate including a plurality of first electrodes and a plurality of second electrodes, which are separated from each other, connecting the plurality of first electrodes to the first auxiliary electrode, and connecting the plurality of second electrodes to the second auxiliary electrode, and a removal operation for removing a portion of the insulating member not overlapping the first and second auxiliary electrodes in the insulating member connected to the back surface of the semiconductor substrate.

The removal operation may be performed using a laser. The removal operation may include dividing the insulating member into a first insulating member overlapping the first auxiliary electrode and a second insulating member overlapping the second auxiliary electrode. The first insulating member may be spatially separated from the second insulating member.

In yet another aspect, there is a solar cell module including a front transparent substrate, a back substrate positioned opposite the front transparent substrate, and a plurality of solar cells positioned between the front transparent substrate and the back substrate, the plurality of solar cells each including a semiconductor substrate including a plurality of first electrodes and a plurality of second electrodes, which are separated from each other on a back surface of the semiconductor substrate, and an insulating member including a first auxiliary electrode connected to the plurality of first electrodes and a second auxiliary electrode connected to the plurality of second electrodes on a front surface of the insulating member, wherein the insulating member is not positioned in a non-formation portion of the first and second auxiliary electrodes of the back surface of the semiconductor substrate.

The first and second auxiliary electrodes may have an electrode wire form, in which the first and second auxiliary electrodes included in one solar cell are connected to electrodes of a different polarity included in another solar cell adjacent to the one solar cell.

The solar cell module may further include a separate metal interconnector positioned between the semiconductor substrates of the adjacent solar cells. Each of the first and second auxiliary electrodes may be connected to the separate metal interconnector.

The insulating member may include a first insulating member overlapping the first auxiliary electrode and a second insulating member overlapping the second auxiliary electrode. The first insulating member may be spatially separated from the second insulating member.

The back surface of the semiconductor substrate may be exposed between the first and second insulating members.

The solar cell module may further include a first encapsulant positioned between the solar cell and the front transparent substrate, and a second encapsulant positioned between the solar cell and the back substrate. The second encapsulant may be charged in a separation space between the first and second insulating members in the back surface of the semiconductor substrate of the solar cell.

### BRIEF DESCRIPTION OF THE DRAWINGS

The accompanying drawings, which are included to provide a further understanding of the invention and are incorporated in and constitute a part of this specification, illustrate embodiments of the invention and together with the description serve to explain the principles of the invention. In the drawings:

FIGS. 1 to 3C illustrate a solar cell according to an example embodiment of the invention;

FIGS. 4 to 8 illustrate a method for manufacturing the solar cell shown in FIGS. 1 to 3C; and

FIG. 9 illustrates a solar cell module using the solar cell shown in FIGS. 1 to 3C.

### DETAILED DESCRIPTION OF THE EMBODIMENTS

Reference will now be made in detail to embodiments of the invention, examples of which are illustrated in the accompanying drawings. This invention may, however, be embodied in many different forms and should not be construed as limited to the embodiments set forth herein. Wherever possible, the same reference numbers will be used throughout the drawings to refer to the same or like parts. It will be noted that detailed description of known arts will be omitted if it is determined that the arts can obscure the embodiments of the invention.

In the following description, “front surface” may be one surface of a solar cell, on which light is directly incident, and “back surface” may be a surface opposite the one surface of the solar cell, on which light is not directly incident or reflective light may be incident.

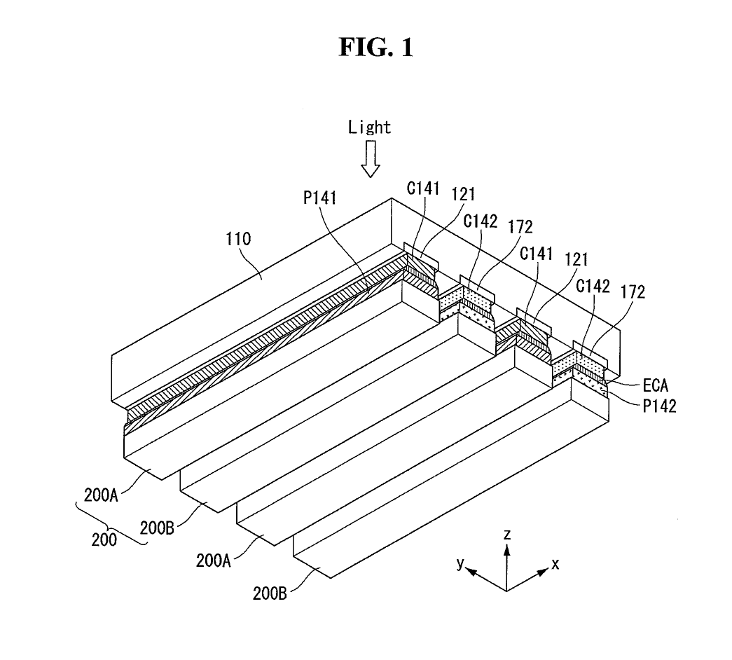

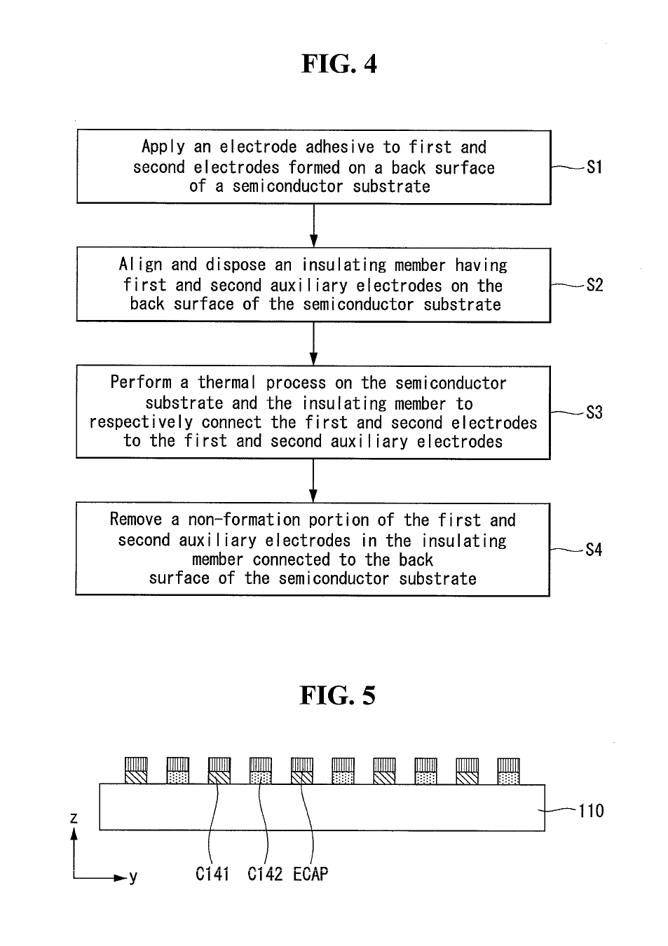

Exemplary embodiments of the invention will be described with reference to FIGS. 1 to 9.

FIGS. 1 to 3C illustrate a solar cell according to an example embodiment of the invention.

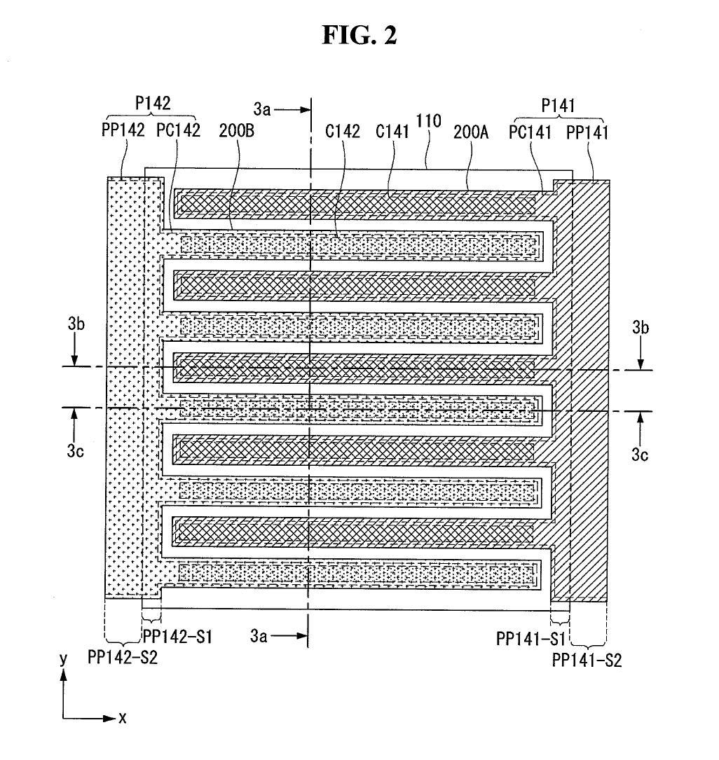

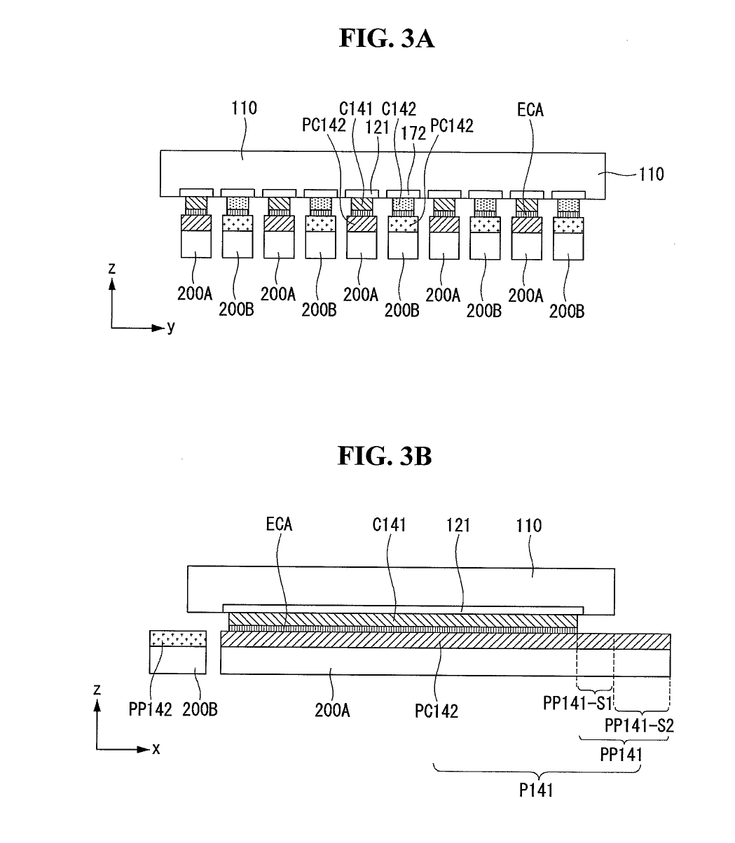

More specifically, FIG. 1 is a partial perspective view of a solar cell according to the embodiment of the invention, and FIG. 2 shows an entire back surface of the solar cell according to the embodiment of the invention. FIG. 3A is a cross-sectional view taken along line 3a-3a of FIG. 2, FIG. 3B is a cross-sectional view taken along line 3b-3b of FIG. 2, and FIG. 3C is a cross-sectional view taken along line 3c-3c of FIG. 2.

As shown in FIG. 1, the solar cell according to the embodiment of the invention may include a semiconductor substrate 110, an emitter region 121, a back surface field (BSF) region 172, a plurality of first electrodes C141, a plurality of second electrodes C142, a first auxiliary electrode P141, a second auxiliary electrode P142, and an insulating member 200.

The solar cell according to the embodiment of the invention may further include an anti-reflection layer positioned on a front surface of the semiconductor substrate 110, on which light is incident.

The semiconductor substrate 110 may be a bulk type semiconductor substrate formed of silicon of a first conductive type, for example, an n-type, though not required. The semiconductor substrate 110 may be formed by doping a wafer formed of silicon material with impurities of the first conductive type.

The front surface of the semiconductor substrate 110 may be textured to form a textured surface corresponding to an uneven surface having a plurality of uneven portions or having uneven characteristics. The anti-reflection layer may be positioned on the front surface of the semiconductor substrate 110 and may include one layer or a plurality of layers. Further, a front surface field region may be additionally formed at the front surface of the semiconductor substrate 110.

The emitter region 121 may be positioned to be separated from one another inside a back surface opposite the front surface of the semiconductor substrate 110 and may extend in a direction parallel to one another. Namely, the emitter region 121 may be in plural. The plurality of emitter regions 121 may contain impurities of a second conductive type (for example, p-type) opposite the first conductive type (for example, n-type) of the semiconductor substrate 110. Thus, the emitter region 121 may form a p-n junction along with the semiconductor substrate 110.

The plurality of emitter regions 121 may heavily contain impurities of the second conductive type (for example, p-type) opposite the first conductive type (for example, n-type) of the semiconductor substrate 110 formed of crystalline silicon and may be formed through a diffusion process.

The plurality of back surface field regions 172 may be positioned inside the back surface of the semiconductor substrate 110. The plurality of back surface field regions 172 may be positioned to be separated from one another in a direction parallel to the plurality of emitter regions 121 and may extend in the same direction as the emitter regions 121. Thus, as shown in FIGS. 1 and 2, the plurality of emitter regions 121 and the plurality of back surface field regions 172 may be alternately positioned at the back surface of the semiconductor substrate 110.

Each back surface field region 172 may be a region (for example, an n⁺⁺-type region) which is more heavily doped than the semiconductor substrate 110 with impurities of the same conductive type as the semiconductor substrate 110. The plurality of back surface field regions 172 may heavily contain impurities (for example, n⁺⁺-type impurities) of the same conductive type as the semiconductor substrate 110 formed of crystalline silicon and may be formed through a diffusion process or a deposition process.

The plurality of first electrodes C141 are positioned on the back surface of the semiconductor substrate 110. As shown in FIG. 1, the plurality of first electrodes C141 are physically and electrically connected to the plurality of emitter regions 121, respectively, extend along the plurality of emitter regions 121, and are separated from one another. Thus, when the emitter regions 121 extend in a first direction x (for example, x-axis direction), the first electrodes C141 may extend in the first direction x. Further, when the emitter regions 121 extend in a second direction y (for example, y-axis direction), the first electrodes C141 may extend in the second direction y.

The plurality of second electrodes C142 are positioned on the back surface of the semiconductor substrate 110 and are separated from the first electrodes C141. The plurality of second electrodes C142 are physically and electrically connected to the semiconductor substrate 110 through the plurality of back surface field regions 172 and extend along the plurality of back surface field regions 172.

Thus, when the back surface field regions 172 extend in the first direction x, the second electrodes C142 may extend in the first direction x. Further, when the back surface field regions 172 extend in the second direction y, the second electrodes C142 may extend in the second direction y.

The first electrodes C141 and the second electrodes C142 are physically separated from each other and electrically insulated from each other on the back surface of the semiconductor substrate 110.

Thus, the first electrode C141 formed on the emitter region 121 may collect carriers (for example, holes) moving to the emitter region 121, and the second electrode C142 formed on the back surface field region 172 may collect carriers (for example, electrons) moving to the back surface field region 172.

The first auxiliary electrode P141 is positioned on the back surface of the semiconductor substrate 110 and is connected to the plurality of first electrodes C141. As shown in FIG. 2, the first auxiliary electrode P141 may include a first connector PC141 and a first pad PP141.

More specifically, as shown in FIG. 2, the first connector PC141 may be formed in the plural, and thus the plurality of first connectors PC141 may be respectively connected to the plurality of first electrodes C141. Each first connector PC141 may extend in the first direction x.

Further, as shown in FIG. 2, one end of the first pad PP141 may be connected to ends of the first connectors PC141 and may extend in the second direction y, and the other end may be connected to an interconnector.

The second auxiliary electrode P142 is positioned on the back surface of the semiconductor substrate 110 to be separated from the first auxiliary electrode P141. As shown in FIG. 2, the second auxiliary electrode P142 may include a second connector PC142 and a second pad PP142.

More specifically, as shown in FIG. 2, the second connector PC142 may be formed in the plural, and thus the plurality of second connectors PC142 may be respectively connected to the plurality of second electrodes C142. Each second connector PC142 may extend in the first direction x.

Further, as shown in FIG. 2, one end of the second pad PP142 may be connected to ends of the second connectors PC142 and may extend in the second direction y, and the other end may be connected to the interconnector.

The first auxiliary electrode P141 and the second auxiliary electrode P142 may be formed of at least one of copper (Cu), gold (Au), silver (Ag), or aluminum (Al).

As shown in FIG. 2, the first pad PP141 and the second pad PP142 may respectively include first areas PP141-S1 and PP142-S1 overlapping the semiconductor substrate 110 and second areas PP141-S2 and PP142-S2 not overlapping the semiconductor substrate 110.

The interconnector may be connected to the second area PP141-S2 of the first pad PP141 and the second area PP142-S2 of the second pad PP142, which are provided to secure a connection space between the interconnector and the first and second pads PP141 and PP142.

Because the first pad PP141 and the second pad PP142 according to the embodiment of the invention respectively include the second areas PP141-S2 and PP142-S2, the connection of the interconnector may be more easily performed. Further, when the interconnector is connected to the first and second pads PP141 and PP142, a thermal expansion stress of the semiconductor substrate 110 may be minimized.

As shown in FIG. 1, the first auxiliary electrode P141 may be electrically connected to the first electrodes C141 using an electrode adhesive ECA formed of a conductive material, and the second auxiliary electrode P142 may be electrically connected to the second electrodes C142 using the electrode adhesive ECA.

The material of the electrode adhesive ECA is not particularly limited as long as it is a conductive material. However, it may be preferable, but not required, that a conductive material having a melting point of a relatively low temperature, for example, about 140° C. to 180° C. is used. However, the embodiment of the invention is not limited thereto. The melting point may vary.

For example, the electrode adhesive ECA may use a solder paste, a conductive paste, in which conductive metal particles are distributed in an insulating resin, or a conductive adhesive film.

The insulating member 200 may be disposed on back surfaces of the first auxiliary electrode P141 and the second auxiliary electrode P142.

A material of the insulating member 200 is not particularly limited as long as it is an insulating material. However, it may be preferable, but not required, that a melting point of the material of the insulating member 200 is relatively high. For example, the insulating member 200 may be formed of at least one of polyimide, epoxy-glass, polyester, or bismaleimide triazine (BT) resin, each of which has a thermal resistance to a high temperature.

The insulating member 200 may be formed in the form of a flexible film or in the form of a hard plate which is not flexible.

In the solar cell according to the embodiment of the invention, the insulating member 200 and the semiconductor substrate 110 may be connected to each other to form an individual element, in a state where the first and second auxiliary electrodes P141 and P142 are previously formed on a front surface of the insulating member 200 and the plurality of first and second electrodes C141 and C142 are previously formed on the back surface of the semiconductor substrate 110.

More specifically, the plurality of first electrodes C141 and the plurality of second electrodes C142 formed on the back surface of one semiconductor substrate 110 may be attached and electrically connected to the first auxiliary electrode P141 and the second auxiliary electrode P142 formed on the front surface of one insulating member 200 through a process for attaching one semiconductor substrate 110 to one insulating member 200 to form one individual integrated type element.

The insulating member 200 functions to facilitate the process performed when the first auxiliary electrode P141 and the second auxiliary electrode P142 are respectively attached to the first electrodes C141 and the second electrodes C142 formed on the back surface of the semiconductor substrate 110.

Namely, when the front surface of the insulating member 200, on which the first auxiliary electrode P141 and the second auxiliary electrode P142 are formed, is attached and connected to the back surface of the semiconductor substrate 110, on which the first electrodes C141 and the second electrodes C142 are formed, through the semiconductor manufacturing process, the insulating member 200 may help in more easily performing an alignment process or a connection step.

Thus, after the first and second auxiliary electrodes P141 and P142 are respectively connected to the first and second electrodes C141 and C142 in the connection step, a portion of the insulating member 200 may be removed.

More specifically, as shown in FIG. 1, the insulating member 200 according to the embodiment of the invention may be omitted in the back surface of the semiconductor substrate 110, on which the first and second auxiliary electrodes P141 and P142 are not formed.

As shown in FIGS. 1 and 2, the insulating member 200 may include a first insulating member 200A overlapping the first auxiliary electrode P141 and a second insulating member 200B overlapping the second auxiliary electrode P142. The first insulating member 200A may be spatially separated from the second insulating member 200B.

The first and second insulating members 200A and 200B may be formed in a portion overlapping the first and second connectors PC141 and PC142 and the first and second pads PP141 and PP142. Further, the first and second insulating members 200A and 200B may not be formed in a portion not overlapping the first and second connectors PC141 and PC142 and the first and second pads PP141 and PP142.

Thus, the back surface of the semiconductor substrate 110 may be exposed to a separation space between the first and second insulating members 200A and 200B.

As shown in FIG. 3A which is a cross-sectional view taken along line 3a-3a of FIG. 2 parallel to the second direction y, the first electrode C141 formed on the back surface of the semiconductor substrate 110 and the first connector PC141 formed on a front surface of the first insulating member 200A may overlap each other and may be electrically connected to each other through the electrode adhesive ECA.

Further, the second electrode C142 formed on the back surface of the semiconductor substrate 110 and the second connector PC142 formed on a front surface of the second insulating member 200B may overlap each other and may be electrically connected to each other through the electrode adhesive ECA.

In the embodiment disclosed herein, the first electrode C141 and the second electrode C142 may be separated from each other, and the first connector PC141 and the second connector PC142 may be separated from each other.

Thus, the back surface of the semiconductor substrate 110 may be exposed to the separation space between the first and second insulating members 200A and 200B.

As shown in FIG. 3B which is a cross-sectional view of the first auxiliary electrode P141 taken along line 3b-3b of FIG. 2 parallel to the first direction x, the first connector PC141 and the second pad PP142 may be separated from each other. Further, the first insulating member 200A formed on a back surface of the first connector PC141 and the second insulating member 200B formed on a back surface of the second pad PP142 may be separated from each other.

As shown in FIG. 3C which is a cross-sectional view of the second auxiliary electrode P142 taken along line 3c-3c of FIG. 2 parallel to the first direction x, the second connector PC142 and the first pad PP141 may be separated from each other. Further, the first insulating member 200A formed on a back surface of the first pad PP141 and the second insulating member 200B formed on a back surface of the second connector PC142 may be separated from each other.

As described above, because the solar cell according to the embodiment of the invention is configured such that the insulating member 200 is not formed in a portion of the back surface of the semiconductor substrate 110, on which the first and second auxiliary electrodes P141 and P142 are not positioned, the embodiment of the invention may prevent a short circuit between the first and second auxiliary electrodes P141 and P142.

Further, when the solar cell is generally applied to a solar cell module, the insulating member 200 having a relatively large thermal expansion coefficient may thermally contract or expand due to heat generated during an operation of the solar cell module. Hence, a deformation of the solar cell may be generated. However, the solar cell according to the embodiment of the invention reduces a formation area of the insulating member 200 and reduces a thermal contraction length and a thermal expansion length of the insulating member 200, thereby securing the long-term reliability of the solar cell module.

So far, the structure of the solar cell according to the embodiment of the invention was described. Hereinafter, a method for manufacturing the solar cell according to the embodiment of the invention is described.

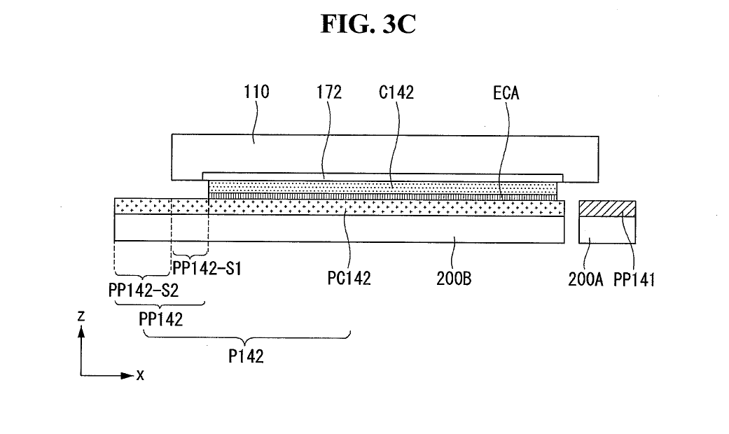

FIGS. 4 to 8 illustrate an example of a method for manufacturing the solar cell shown in FIGS. 1 to 3C.

A method for manufacturing the solar cell according to the embodiment of the invention may include a connection step for connecting the insulating member 200 having the first auxiliary electrode P141 and the second auxiliary electrode P142, which are separated from each other, to the back surface of the semiconductor substrate 110 having the plurality of first electrodes C141 and the plurality of second electrodes C142, which are separated from each other, and a removal step for removing a portion of the insulating member 200 not overlapping the first and second auxiliary electrodes P141 and P142 in the insulating member 200 connected to the back surface of the semiconductor substrate 110.

More specifically, a paste ECAP for forming the electrode adhesive ECA may be applied to the first and second electrodes C141 and C142 formed on the back surface of the semiconductor substrate 110, so as to connect the insulating member 200 to the back surface of the semiconductor substrate 110, in step S1.

In the embodiment disclosed herein, the paste ECAP for forming the electrode adhesive ECA may use one of a solder paste, a conductive paste, and a conductive adhesive film.

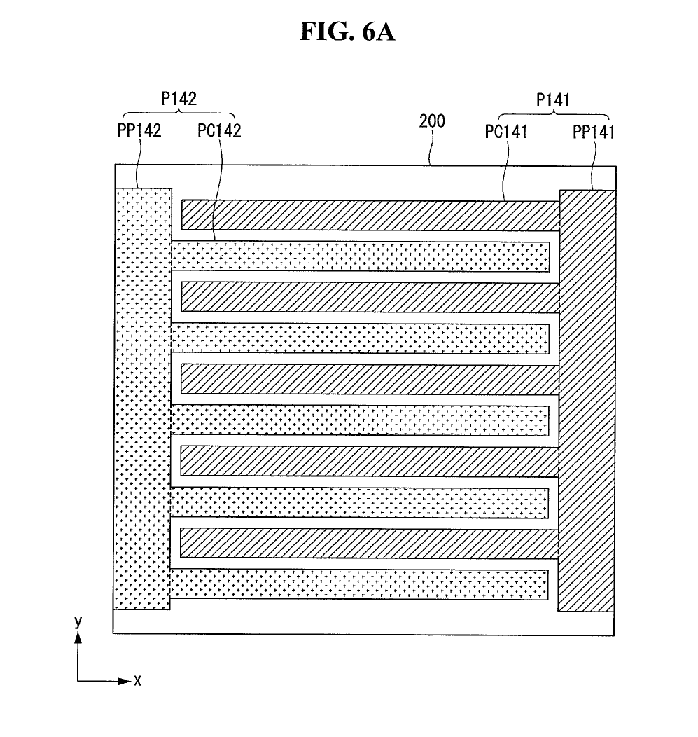

Next, as shown in FIGS. 6A and 6B, the insulating member 200 having the first and second auxiliary electrodes P141 and P142 may be aligned and disposed on the back surface of the semiconductor substrate 110 in step S2.

In this instance, as shown in FIG. 6A, the insulating member 200 may be formed in a non-formation portion of the first and second auxiliary electrodes P141 and P142 as well as a formation portion of the first and second auxiliary electrodes P141 and P142. The insulating member 200 functions to more easily perform the connection process as described above. In this instance, a pattern of the first and second auxiliary electrodes P141 and P142 may use the pattern described above.

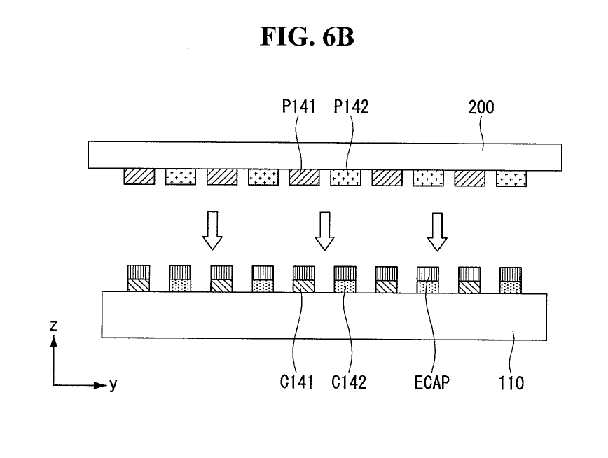

Next, as shown in FIG. 7, a thermal process is performed on the semiconductor substrate 110 and the insulating member 200 to cure the paste ECAP, thereby forming the electrode adhesive ECA. Hence, the plurality of first electrodes C141 may be connected to the first auxiliary electrode P141, and the plurality of second electrodes C142 may be connected to the second auxiliary electrode P142 in step S3.

In this instance, the thermal process may be performed for about 10 minutes to 20 minutes, and a temperature of the thermal process may be about 140° C. to 180° C.

The method may remove the non-formation portion of the first and second auxiliary electrodes P141 and P142 in the insulating member 200 connected to the back surface of the semiconductor substrate 110 in a state where the semiconductor substrate 110 and the insulating member 200 are connected to each other, in step S4.

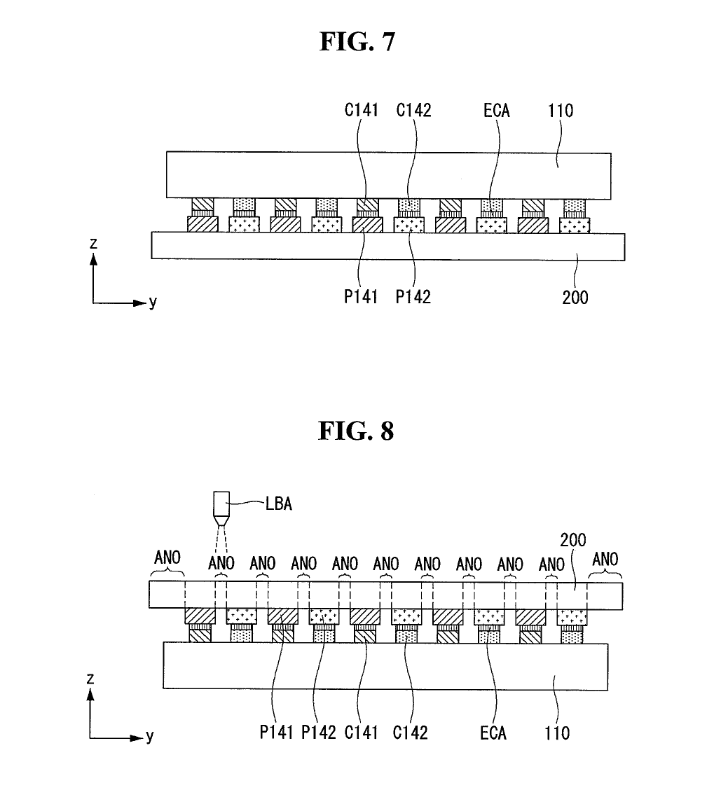

Namely, as shown in FIG. 8, a non-formation portion ANO of the first and second auxiliary electrodes P141 and P142 (or a portion ANO not overlapping the first and second auxiliary electrodes P141 and P142) may be removed in the insulating member 200.

The removal step may be performed by locally and selectively irradiating a laser onto the portion ANO using a laser irradiation device LBA.

As described above with reference to FIGS. 1 to 3C, the insulating member 200 may be divided into the first insulating member 200A overlapping the first auxiliary electrode P141 and the second insulating member 200B overlapping the second auxiliary electrode P142 through the removal step.

Thus, the back surface of the semiconductor substrate 110 may be exposed to a separation space between the first and second insulating members 200A and 200B through the removal step.

Hereinafter, an example of a solar cell module, to which the solar cell according to the embodiment of the invention is applied, is described.

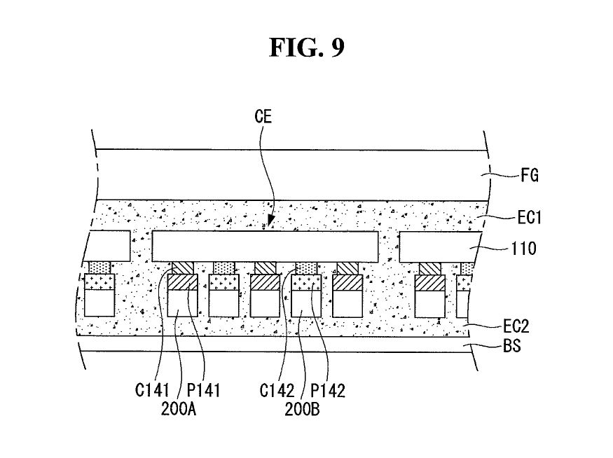

FIG. 9 illustrates an example of a solar cell module using the solar cell shown in FIGS. 1 to 3C.

As shown in FIG. 9, a solar cell module according to the embodiment of the invention may include a front transparent substrate FG, a first encapsulant EC1, a plurality of solar cells CE, a second encapsulant EC2, and a back sheet BS.

The front transparent substrate FG may be positioned on front surfaces of the plurality of solar cells CE. The front transparent substrate FG may be formed of a tempered glass having a high transmittance and a damage prevention function.

The first encapsulant EC1 may be positioned between the front transparent substrate FG and the plurality of solar cells CE, and the second encapsulant EC2 may be positioned on back surfaces of the plurality of solar cells CE, namely, between the back sheet BS and the plurality of solar cells CE.

The first encapsulant EC1 and the second encapsulant EC2 may be formed of a material which prevents corrosion of a metal resulting from the moisture penetration and protects the solar cell module from an impact.

As shown in FIG. 9, a lamination process is performed in a state where the first encapsulant EC1 and the second encapsulant EC2 are respectively positioned on and under the plurality of solar cells CE, and thus the first encapsulant EC1, the second encapsulant EC2, and the plurality of solar cells CE may form one body.

The first encapsulant EC1 and the second encapsulant EC2 may be formed of ethylene vinyl acetate (EVA). Other materials may be used.

The back sheet BS of a sheet type may be positioned on a back surface of the second encapsulant EC2 and may prevent the moisture from penetrating into a back surface of the solar cell module.

When the back sheet BS is formed in the sheet type, the back sheet BS may be formed of an insulating material, for example, FP/PE/FP (fluoropolymer/polyester/fluoropolymer).

In the embodiment disclosed herein, each of the plurality of solar cells CE may use the solar cell shown in FIGS. 1 to 3C.

Thus, in each solar cell CE, an insulating member 200 may not be formed in a non-formation portion of first and second auxiliary electrodes P141 and P142 of a back surface of a semiconductor substrate 110. The insulating member 200 may include a first insulating member 200A overlapping the first auxiliary electrode P141 and a second insulating member 200B overlapping the second auxiliary electrode P142.

The first insulating member 200A may be spatially separated from the second insulating member 200B.

As shown in FIG. 9, in the solar cell module according to the embodiment of the invention, the second encapsulant EC2 may be charged in a separation space between the first and second insulating members 200A and 200B in the back surface of the semiconductor substrate 110 through the above lamination process.

Hence, the second encapsulant EC2 may be charged between the first and second electrodes C141 and C142 and between the first and second auxiliary electrodes P141 and P142 in each solar cell CE. As a result, an insulation function between the first and second electrodes C141 and C142 and an insulation function between the first and second auxiliary electrodes P141 and P142 may be further improved.

The example of the solar cell module using the solar cell shown in FIGS. 1 to 3C was described in FIG. 9.

In the solar cell shown in FIGS. 1 to 3C according to the embodiment of the invention, the first and second auxiliary electrodes P141 and P142 are connected to a separate metal interconnector formed between the semiconductor substrates of the adjacent solar cells.

However, the solar cell module according to the embodiment of the invention may use an electrode wire type solar cell, in which first and second auxiliary electrodes are connected to electrodes of a different polarity in other solar cell adjacent to the solar cell, in addition to the solar cell shown in FIGS. 1 to 3C.

For example, when a first auxiliary electrode P141 is connected to first electrodes C141 of one solar cell, the first auxiliary electrode P141 of the one solar cell may be electrically connected to second electrodes C142 of other solar cell adjacent to the one solar cell.

Further, when a second auxiliary electrode P142 is connected to second electrodes C142 of the one solar cell, the second auxiliary electrode P142 of the one solar cell may be electrically connected to first electrodes C141 of the other solar cell adjacent to the one solar cell.

Although embodiments have been described with reference to a number of illustrative embodiments thereof, it should be understood that numerous other modifications and embodiments can be devised by those skilled in the art that will fall within the scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A solar cell comprising:
a semiconductor substrate including a plurality of first electrodes and a plurality of second electrodes, which are separated from each other on a back surface of the semiconductor substrate; and
an insulating member including a first auxiliary electrode connected to the plurality of first electrodes and a second auxiliary electrode connected to the plurality of second electrodes on a front surface of the insulating member,
wherein the insulating member is positioned on portions of the first and second auxiliary electrodes disposed on the back surface of the semiconductor substrate, and also extends over non-formation portions of the first and second auxiliary electrodes.

2. The solar cell of claim 1, wherein the insulating member includes a first insulating member overlapping the first auxiliary electrode and a second insulating member overlapping the second auxiliary electrode, and
wherein the first insulating member is spatially separated from the second insulating member.

3. The solar cell of claim 2, wherein the back surface of the semiconductor substrate is exposed to a separation space between the first and second insulating members.

4. The solar cell of claim 2, wherein the first auxiliary electrode includes a plurality of first connectors, which are connected to the plurality of first electrodes and extend in a first direction, and a first pad which are connected to ends of the plurality of first connectors and extend in a second direction,
wherein the second auxiliary electrode includes a plurality of second connectors, which are connected to the plurality of second electrodes and extend in the first direction, and a second pad which are connected to ends of the plurality of second connectors and extend in the second direction.

5. The solar cell of claim 4, wherein the first and second insulating members are formed in a portion overlapping the first and second connectors and the first and second pads.

6. The solar cell of claim 4, wherein the first insulating member or the second insulating member is not formed in a portion not overlapping the first and second connectors and the first and second pads.

7. A method for manufacturing a solar cell, the method comprising:
a connection operation for connecting an insulating member including a first auxiliary electrode and a second auxiliary electrode, which are separated from each other, to a back surface of a semiconductor substrate including a plurality of first electrodes and a plurality of second electrodes, which are separated from each other, connecting the plurality of first electrodes to the first auxiliary electrode, and connecting the plurality of second electrodes to the second auxiliary electrode; and
a removal operation for removing a portion of the insulating member not overlapping the first and second auxiliary electrodes in the insulating member connected to the back surface of the semiconductor substrate.

8. The method of claim 7, wherein the removal operation is performed using a laser.

9. The method of claim 7, wherein the removal operation includes dividing the insulating member into a first insulating member overlapping the first auxiliary electrode and a second insulating member overlapping the second auxiliary electrode.

10. The method of claim 9, wherein the first insulating member is spatially separated from the second insulating member.

11. A solar cell module comprising:
a front transparent substrate;
a back substrate positioned opposite the front transparent substrate; and
a plurality of solar cells positioned between the front transparent substrate and the back substrate, the plurality of solar cells each including a semiconductor substrate including a plurality of first electrodes and a plurality of second electrodes, which are separated from each other on a back surface of the semiconductor substrate, and an insulating member including a first auxiliary electrode connected to the plurality of first electrodes and a second auxiliary electrode connected to the plurality of second electrodes on a front surface of the insulating member,
wherein the insulating member is not positioned in a non-formation portion of the first and second auxiliary electrodes of the back surface of the semiconductor substrate.

12. The solar cell module of claim 11, wherein the first and second auxiliary electrodes have an electrode wire form, in which the first and second auxiliary electrodes included in one solar cell are connected to electrodes of a different polarity included in another solar cell adjacent to the one solar cell.

13. The solar cell module of claim 12, further comprising a separate metal interconnector positioned between the semiconductor substrates of the adjacent solar cells,
wherein each of the first and second auxiliary electrodes is connected to the separate metal interconnector.

14. The solar cell module of claim 11, wherein the insulating member includes a first insulating member overlapping the first auxiliary electrode and a second insulating member overlapping the second auxiliary electrode, and
wherein the first insulating member is spatially separated from the second insulating member.

15. The solar cell module of claim 14, wherein the back surface of the semiconductor substrate is exposed between the first and second insulating members.

16. The solar cell module of claim 14, further comprising:
a first encapsulant positioned between the solar cell and the front transparent substrate; and
a second encapsulant positioned between the solar cell and the back substrate,
wherein the second encapsulant is charged in a separation space between the first and second insulating members in the back surface of the semiconductor substrate of the solar cell.
